(19) United States
(12) Patent Application Publication
(10) Pub. No.: US 2018/0182934 A1
(43) Pub. Date: Jun. 28, 2018

(54) Light Emitting Unit

(71) Applicant: OSRAM Opto Semiconductors GmbH, Regensburg (DE)

(72) Inventors: I-Hsin Lin-Lefebvre, Regensburg (DE); Reinhard Streitel, Laaber (DE); Darshan Kundaliya, Beverly, MA (US); Tobias Gebuhr, Regensburg (DE)

(21) Appl. No.: 15/389,213

(22) Filed: Dec. 22, 2016

(51) Int. Cl. H01L 33/50; H01L 33/62

(52) U.S. Cl. CPC H01L 33/508; H01L 33/507; H01L 33/62; H01L 2933/0066; H01L 33/505; H01L 2933/0041; H01L 33/502

(57) ABSTRACT

A light emitting unit includes a light emitting semiconductor chip and a wavelength converter for the light of the semiconductor chip. The wavelength converter has a substrate with a first surface. The first surface includes a rough surface with recesses. The wavelength converter has a conversion layer that is arranged on the first surface of the substrate. The conversion layer has luminescent materials. A connecting layer is arranged between the wavelength converter and a light emitting surface of the light emitting semiconductor chip.

### TECHNICAL FIELD

This invention relates to a light emitting unit and to a method for producing a light emitting structure with a converter.

### SUMMARY

A light emitting unit with a light emitting semiconductor chip and a wavelength converter for the light of the semiconductor chip is provided. The converter has a substrate with a first surface, wherein the first surface comprises a rough surface with recesses. The converter has a conversion layer which is arranged on the first surface of the substrate. The conversion layer has luminescent materials, wherein a connecting layer is arranged between the converter and a light emitting surface of the light emitting semiconductor chip.

In a further embodiment, the connecting layer is arranged between a second surface of the substrate of the converter and the light emitting surface of the light emitting semiconductor chip.

In a further embodiment, the connecting layer is arranged between the conversion layer of the converter and a light emitting surface of the light emitting semiconductor chip.

The light emitting surface of the light emitting semiconductor chip may be at the top side of the light emitting semiconductor chip or at the bottom side of the light emitting semiconductor chip. The light emitting surface of the light emitting unit can be embodied as a surface of the semiconductor structure or as a surface of a substrate on which the semiconductor structure is arranged.

In one embodiment, in which the connecting layer preferably comprises silicone, the connecting layer provides an adhesive connection between the converter and the light emitting semiconductor chip. Silicone allows a particular secure connection that can be easily performed.

In an embodiment, the connecting layer has a thickness smaller than 10 μm. This thickness provides a sufficient strong fixing and a small light absorption.

In an embodiment, the connecting layer comprises an inorganic material, for example, glass, wherein the converter and the semiconductor chip are connected by fusion bonding layers to the connecting layer. The inorganic material is stable at high temperature and at a high light flux.

In an embodiment, the connecting layer is provided as a foil. The foil has the advantage that the shape of the connecting layer can be precisely determined. Furthermore, the foil has the advantage that the connecting layer can be arranged only in predetermined areas. Furthermore, the foil can be used for easily connecting larger areas.

In an embodiment, the connecting layer is a fusion bonding layer that connects the lower surface of the substrate with a semiconductor chip. Therefore, it is not necessary to provide a separate material for the connecting layer.

In an embodiment, the light emitting surface of the semiconductor chip is made of semiconductor materials, and the chip substrate of a light emitting semiconductor chip may be sapphire or silicon. Semiconductor material, especially silicon and sapphire have suitable chemical, physical and optical properties for the proposed connections.

In an embodiment, the substrate is made of sapphire. Sapphire has suitable chemical, physical and optical properties for the proposed converter and the proposed connections.

In an embodiment, the conversion layer has a second surface, wherein the second surface is opposite to the substrate, and wherein the second surface has second recesses, and wherein the second recesses have the same shape or similar shape as the recesses of the substrate. Therefore low reflection of the light at the material interfaces is attained.

In an embodiment, the conversion layer comprises or consists of an epitaxial or polycrystalline or amorphous layer of luminescent materials, wherein the conversion layer has a thickness smaller than 100 μm for example smaller than 50 μm or smaller than 20 μm. Since there is no matrix material, low light absorption without conversion and a high thermal conductivity is provided.

A method for producing a light emitting unit with a converter is provided. A light emitting semiconductor structure with a light emitting surface is provided. A substrate with a first surface is provided. The first surface is a rough surface with recesses. A conversion layer is arranged on the first surface of the substrate forming a wavelength converter. The conversion layer has luminescent materials. The connecting layer is formed between the converter and a light emitting surface of the light emitting semiconductor chip, wherein the connecting layer fixes the converter to the light emitting semiconductor chip. This is a simple and reliable method for producing a light emitting unit with a converter.

In an embodiment, the connecting layer is formed between a second surface of the substrate of the converter and a light emitting surface of the light emitting semiconductor chip.

In an embodiment, the connecting layer is formed between the conversion layer of the converter and the light emitting surface of the light emitting semiconductor chip.

In an embodiment, the light emitting semiconductor structure can be a part of a wafer, wherein after the connection of the wafer with the converter by means of the connecting layer, the wafer with the connecting layer and the converter is separated in single light emitting units. The light emitting unit has a part of a wafer, a light emitting semiconductor structure, a connecting layer and a converter. This embodiment allows a simple method to produce a lot of light emitting units.

In an embodiment, the light emitting semiconductor structure can be a part of a light emitting semiconductor chip. Therefore, the method can also be used to connect a single light emitting semiconductor chip with a converter, or to connect multiple light emitting semiconductor chips with a converter.

In an embodiment, the light emitting semiconductor structure can be embedded in a molding material performing by a film assisted molding process, wherein during the molding process, a film protects a second surface of the conversion layer from molding material.

In an embodiment, the light emitting unit can be embedded in a molding material performing via a film assisted molding process, wherein during the molding process, a film protects an upper side of the light emitting unit. The film protects the upper side of the light emitting unit against damage.

In a further embodiment, the upper side of the light emitting unit is embodied as a second surface of the conversion layer, wherein during the molding process the film protects the second surface of the conversion layer from molding material.

Especially with a rough second surface comprising recesses, the film provides a sufficient sealing against the molding material. Therefore, a covering on the second surface of the conversion layer with molding material is prevented. Furthermore, the film protects the second surface of the conversion layer against damage.

In comparison with conventional transfer molding techniques, the film-assisted molding technique allows a back-end assembly sequence to proceed up to the conversion layer assembly prior to the molding, which opens an alternative lead frame and/or housing design and simplifies traditional back-end packaging procedures. Additional merits arising from the film-assisted molding technique include a thoroughly controlled molded encapsulate thickness across the whole housing which is not easily achieved via casting or dispensing methods.

In an embodiment, the connecting layer comprises silicone and is arranged between the converter and the light emitting surface of the semiconductor chip. The converter is fixed to the light emitting semiconductor chip by a lamination process that generates an adhesive connection between the substrate and the light emitting semiconductor chip by means of the connecting layer.

In an embodiment, the connecting layer comprises an inorganic material and is arranged between the converter and the light emitting surface of the semiconductor chip. The converter is fixed to the light emitting semiconductor chip by a fusing process that generates a fusion bonding connection between the substrate and the light emitting semiconductor chip by means of the connecting layer. The inorganic material may comprise glass or may be made of glass.

In a further embodiment, the connecting layer is provided as a foil. The processing of the foil can be easily performed. The foil provides a defined shape of the connecting layer with respect to a length, a width and a thickness.

In a further embodiment, the converter is added onto the light emitting semiconductor chip, wherein the converter is directly connected with the light emitting semiconductor chip by a fusion bonding process. Therefore it is not necessary to arrange a separate material for forming the connecting layer.

The converter can be either with the substrate side or with the conversion layer side directly or with a layer in between connected to the light emitting semiconductor chip. The light emitting surface of the light emitting semiconductor structure is a surface of the semiconductor structure or a surface of a substrate which is arranged on the semiconductor structure.

In a further embodiment, the light emitting surface of the light emitting semiconductor chip is made of semiconductor materials. The chip substrate of a light emitting semiconductor chip may be made of sapphire.

The light emitting semiconductor chip may be for example embodied as a light emitting diode or a laser diode.

### BRIEF DESCRIPTION OF THE DRAWINGS

The above-described properties, features and advantages of this invention and the way in which they are achieved will become clearer and more clearly understood in association with the following exemplary embodiment descriptions, which are explained in greater detail in association with the drawings. Here in schematic illustration in each case:

FIG. 1 schematically shows a cross section of a substrate and a conversion layer of a converter.

FIG. 2 shows a cross section of a wafer with a converter.

FIG. 3 shows a schematic perspective view of the wafer with the converter with dicing lines.

FIG. 4 shows an embodiment of a light emitting unit.

FIG. 5 shows a schematic view of a patterned sapphire substrate with projections.

FIG. 6 shows a schematic view of a partial cross section of the patterned sapphire substrate of FIG. 5.

FIG. 7 shows cross sections of examples of projections with different shapes.

FIG. 8 shows a schematic cross-sectional view of a deposited conversion layer on the sapphire substrate of FIG. 5.

FIG. 9 shows a top view of the first surface of a substrate with an irregularly structured first surface.

FIG. 10 shows a top view of the first surface of a further substrate with a regularly structured first surface.

FIG. 11 shows a schematic illustration of an apparatus for a pulsed laser deposition.

FIG. 12 shows a tool for a film-assisted molding process.

FIG. 13 shows the tool of FIG. 12 during the film-assisted molding process.

FIG. 14 shows a schematic perspective view of an embedded light emitting unit.

FIG. 15 shows a further example of an embedded light emitting unit.

FIG. 16 shows a cross section of a further embodiment of a converter with a conversion layer with a rough surface that is directed to the upper surface of the wafer.

FIG. 17 shows a further example of an embedded light emitting unit mounted on a printed circuit board.

FIG. 18 shows a further example of an embedded light emitting unit mounted on lead frames.

FIG. 19 shows a further example of an embedded light emitting unit mounted as a flip chip on a printed circuit board.

FIG. 20 shows a further example of an embedded light emitting unit mounted as a flip chip on a printed circuit board.

FIG. 21 shows a further example of an embedded light emitting unit mounted as a flip chip on lead frames.

FIG. 22 shows a further example of an embedded light emitting unit mounted as a flip chip on lead frames.

FIG. 23 shows an example of a flip chip top emitter with a converter attached.

FIG. 24 shows an example of a flip chip volume emitter with a converter attached.

FIG. 25 shows an example for a top emitter with a converter attached.

FIG. 26 shows an example for a volume emitter with a converter attached.

FIG. 27 shows an example for a sapphire top emitter with a converter attached.

FIG. 28 shows an example for a sapphire chip with a converter attached.

FIG. 29 shows a top view of a semiconductor chip with a converter with recesses.

FIG. 30 shows a top view of a further semiconductor chip with a converter with recesses.

### DETAILED DESCRIPTION OF ILLUSTRATIVE EMBODIMENTS

For a better understanding of the present invention, together with other and further objects, advantages and capabilities thereof, reference is made to the following disclosures and appended claims taken in conjunction with the above described drawings.

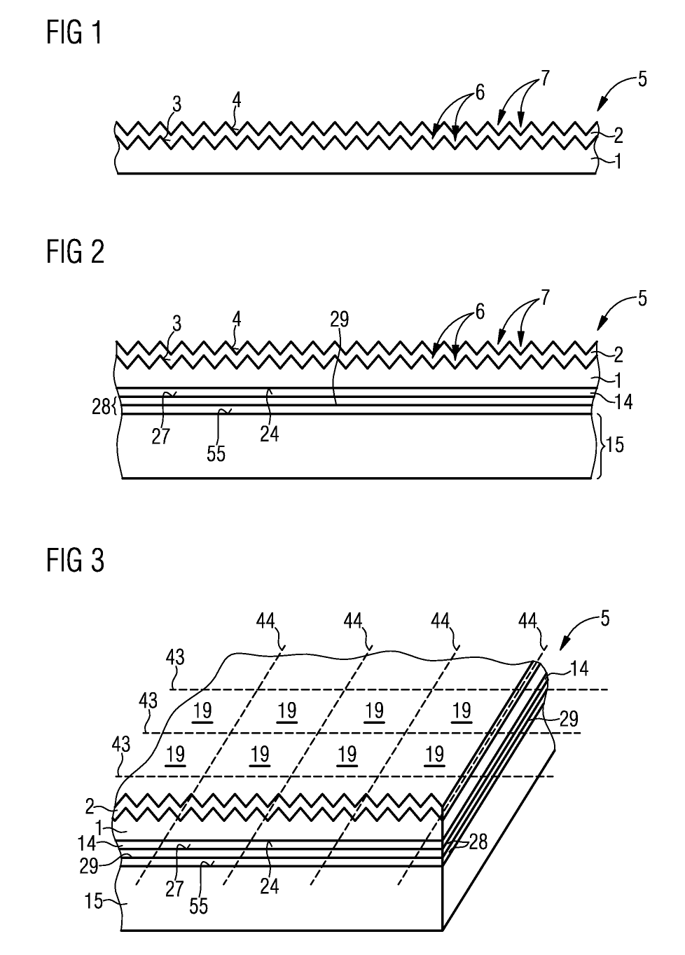

FIG. 1 shows a schematic cross section of a converter 5 with a substrate 1 and a conversion layer 2. The substrate 1 comprises a first surface 3. The conversion layer 2 is arranged on the first surface 3 of the substrate 1. The conversion layer 2 comprises opposite to the substrate 1 a second surface 4. In the shown embodiment the first surface 3 is not embodied as a plane surface but has a structured surface with first recesses 6. Therefore the first surface 3 has a rough surface. In the shown embodiment, the second surface 4 of the conversion layer 2 is not embodied as a plane surface but has a second surface with second recesses 7. The first and the second recesses 6, 7 are of similar and/or identical shape. The first and the second recesses 6,7 have for example a similar shape if the shapes of the first and the second recesses differ less than 50% with respect to a height, a width, and/or an angular inclination of faces. Also, a pattern of the first recesses of the first surface is similar or identical to the pattern of the second recesses of the second surface. The meaning of recess covers any type of opening and any type of shape. Furthermore, the meaning of recess also covers an etched recess, especially an etched surface of a crystalline material.

For example, the first and second recesses can be arranged in a regular pattern. Furthermore, the first and second recesses can be arranged in a random pattern. The shape of the first recess and/or the shape of the second recess can be symmetric or asymmetric, for example, with respect to a middle plane or a middle axis of the first recess or respectively to a middle plane or a middle axis of the second recess.

Experiments have shown that a converter 5 with a substrate 1 with a structured first surface 3 with first recesses 6 improves the light transmission from the substrate 1 to the conversion layer 2. Furthermore, experiments have shown that a conversion layer 2 with a second structured surface 4 improves the light transmission from the conversion layer 2 through the second surface 4. Depending on the used embodiment, the first and/or the second surface 3, 4 can also be embodied as flat or even surfaces.

The conversion layer 2 may be embodied as a single layer or as a stack of several layers. The layers of the stack can be made of the same material or of different materials. The thickness of the layers of the stack can be equal or different. The conversion layer 2 comprises luminescent materials or is made of luminescent materials. At least one layer or each layer of the stacks of the conversion layer 2 may comprise a luminescent material or may be made of luminescent materials. The conversion layer may comprise or may be made of crystalline luminescent materials that are epitaxially deposited on lattice matched substrates. The conversion layer may comprise or may be made of polycrystalline luminescent materials. A thin conversion layer has the advantage to reduce light scattering within the conversion layer and to improve light transmission through the conversion layer. Furthermore, thin conversion layer 2 also shows an improved heat dissipation compared to thicker conversion layers. Additionally, the optical and physical properties of the conversion layer are improved by using a conversion layer that is made of luminescent materials without comprising matrix material e.g., silicone or ceramic.

Regarding luminescent materials, for example, the family of cerium-activated garnets represented by the general formula A₃B₅O₁₂:Ce can be used, wherein A is Y, Sc, La, Gd, Lu or Tb and B is Sc, Al or Ga. These garnet-based phosphors have a cubic lattice structure and absorb wavelength in the range from 420 nm to 490 nm, which means that they are excitable by radiation from a blue light source such as a blue LED. The garnet phosphors, cerium-activated yttrium aluminum garnet, Y₃Al₅O₁₂:Ce (YAG:Ce) has been in widespread use in commercial light-emitting phosphor conversion LEDs. The YAG:Ce phosphor has been shown a very efficient converter for a blue wavelength and can generate a broad intense yellow emission band centered at about 575 nm. For example YAG:Ce can be deposited as a monocrystalline layer on a substrate made of YAG or Gd₃Ga₅O₁₂.

In a further embodiment, the wavelength converting material may be selected from one or more of nitride phosphors such as M₂Si₅N₈:Eu<2+>, wherein M=Ca, Sr, Ba; oxynitride phosphors such as MSi₂O₂N₂:Eu<2+>, wherein M=Ca, Sr, Ba; and silicate phosphors such as BaMgSi₄O₁₀:Eu<2+>, and M₂SiO₄:Eu<2+>, wherein M=Ca, Ba, Sr. Alternatively or additionally, the wavelength converting material may be selected from MAlSiN₃:Eu, wherein M is a metal selected from Ca, Sr, Ba, and A₂O₃:Re<3+> wherein A is selected from Sc, Y, La, Gd, Lu and Re<3+> is a trivalent rare earth ion such as Eu<3+>.

Depending on the used embodiment, also other luminescent materials can be used to provide a conversion layer.

Depending on the used embodiment, the conversion layer 2 may be embodied to convert light of a certain wavelength and/or color, for example, UV light and/or blue light and/or green light and/or red light and/or IR light, into light of a different wavelength and/or color.

The substrate 1 can be embodied for example, as a sapphire substrate or a sapphire wafer. But also other light transparent materials, for example, fused silica (quartz glass), Y₃Al₅O₁₂, Gd₃Ga₅O₁₂, ZnO, SrTiO₃, and yttria stabilized ZrO₂ (YSZ) can be used as substrate 1. A material is transparent if at least 50% of the incident light goes through the material without absorption. A converter is provided that is made of an epitaxial grown crystalline luminescent material. Experiments have shown that the crystalline luminescent material can be deposited with a small thickness and a high wavelength conversion efficiency. Additionally, the crystalline luminescent material can be deposited with good physical properties on the substrate, especially on a crystalline substrate. The substrate can, for example, be made of sapphire, in particular, pre-patterned sapphire (PPS).

The first surface 3 can comprise any kind of rough structure with recesses. The rough structure may be embodied with a regular pattern or with a random pattern. The first surface 3 that comprises recesses 6 may be produced by mechanical processes for example, by a mechanical polishing process and/or a mechanical chemical polishing process. Furthermore, the first recess 6 of the first surface 3 of the substrate 1 can be generated by a chemical etching process. For example, the first surface 3, especially for a sapphire substrate, may be structured in a hexagonal pattern with projections, wherein the projections are arranged with a pitch of about 3.5 μm between two projections. The projections may have a height of about 1.2 to 1.6 μm. The projections may have a width of about 0.5 to 1 μm. The projections may have a shape of a cone with a nearly constant diameter or with a decreasing diameter in a direction to a tip of the cone. The first recess of the first surface of the substrate and/or the second recess of the second surface of the conversion layer can be arranged in a regular pattern or in a random pattern. Furthermore, the first recess can have similar or identical shapes or different shapes. Furthermore, the second recess can have a similar or identical shape or different shapes. Furthermore, the first recess and the second recess can have a similar or identical shape. Experiments have shown that the first and/or the second recess(es) can be defined by projections with a height of about five micrometers or less. The first surface may comprise projections that define the recesses, wherein the projections are arranged with a pitch distance of 10 μm or less, preferably with a pitch distance of 3 μm or less.

The deposition of the conversion layer 2 may be performed by a pulsed laser deposition process, a sputtering process, an electron-beam deposition process, an ion beam assisted pulsed laser deposition process and/or by an aerosol deposition process. Especially the pulsed laser deposition process provides a method to deposit the conversion layer in short time.

Since the deposited conversion layer 2 has a small thickness that may be smaller than 50 μm or smaller than 20 μm, the structured shape of the first surface 3 is easier to be transferred to a (structured) second surface 4 of the conversion layer 2. Therefore, there is no need to structure the conversion layer 2 after the deposition of the conversion layer 2.

The substrate may have a thickness of about 650 μm. Depending on the used embodiment, the substrate may have a smaller thickness or a larger thickness. The substrate may have a thickness smaller than 1 mm. The substrate may have a relative thickness compared to the conversion layer that is between 1:200 and 1:10, where the substrate is expediently thicker than the conversion layer.

FIG. 2 shows the converter 5 that is fixed by a connecting layer 14 to an upper surface 27 of a semiconductor structure 28 that is arranged on an upper surface 55 of a wafer 15. The semiconductor structure 28 comprises several semiconducting layers with an active region, e.g., a pn interface 29, that is embodied to generate light. The semiconductor structure 28 is, for example, made of epitaxial layers of semiconductor materials combining group III elements with group V elements, for example, boron, aluminum, gallium, indium with nitrogen, phosphorus, arsenic, antimony, bismuth. The range of possible formulae is quite broad because these elements can form binary (two elements, e.g. gallium(III) arsenide (GaAs)), ternary (three elements, e.g. indium gallium arsenide (InGaAs)) and quaternary (four elements, e.g. aluminum gallium indium phosphide (AlInGaP)) alloys.

A second, lower surface 24 of the substrate 1 of the converter 5 is arranged on the connecting layer 14. The connecting layer 14 is arranged on the upper surface 27 of the semiconductor structure 28. The connecting layer 14 may be embodied as a foil which means a sheet layer. The connecting layer 14 may have the same area as the semiconductor structure 28 or the wafer 15. The connecting layer 14 may have a thickness smaller than 10 μm, preferably smaller than 5 μm, for example, 1 μm. However, the connecting layer 14 may also have a larger thickness.

The connecting layer 14 may, for example, comprise silicone or may be embodied as a silicone layer. The connecting layer 14 may comprise a silicone matrix material based on methyl or phenyl. Furthermore, the connecting layer 14 with silicone may comprise filler, for example, spacer particles made of TiO₂ or SiOₓ. The connecting layer 14 may have a thickness smaller than 10 μm, preferably smaller than 5 μm. The connecting layer 14 is made of a material that is transparent for at least 50% of the light that is emitted by the light emitting semiconductor structure 28.

The connecting layer 14 may, for example, be embodied as a silicone layer. The connecting layer 14 may comprise a silicone matrix based on methyl or phenyl. Furthermore, the connecting layer may comprise filler material for example spacer and/or TiO₂ and/or SiOₓ.

The connecting layer 14 is, for example, arranged between the lower surface 24 of the substrate 1 of the converter 5 and the upper surface 27 of the light emitting semiconductor structure 28 of the wafer 15. The connecting layer with silicone is an adhesive layer. The converter 5 is fixed to the wafer 15 by a lamination process that generates an adhesive connection between the substrate and the connecting layer and between the connecting layer and the wafer 15. The lamination process can be performed at room temperature or at higher temperatures above 100° C.

In a further embodiment, the connecting layer comprises inorganic material for example glass or is made of inorganic material for example glass. In this embodiment, the connecting layer is arranged between the lower surface 24 of the substrate 1 of the converter 5 and the upper surface 27 of the semiconductor structure 28. The converter 5 is fixed to the semiconductor structure 28 by an inorganic fusing process, for example a glass fusing process that generates an inorganic fusion bonding, for example a glass fusion bonding connections between the substrate and the connecting layer and between the connecting layer and the semiconductor structure 28. The inorganic fusing process, especially the glass fusing process is performed at temperatures up to a melting point of the inorganic material, especially the glass material. In a further embodiment, the connecting layer comprises or is made of silicon dioxide. Furthermore, a laser welding process is also suitable to join a converter with a light emitting semiconductor structure 28. Depending on the used embodiment, the semiconductor structure 28 is arranged on a wafer 15 or an a semiconductor chip. For the semiconductor chip the same connecting processes can be used as explained for the wafer 15.

In a further embodiment, the connecting layer is generated by a fusing process without providing a separate connecting layer material. The lower surface 24 of the substrate 1 is put on the upper surface 27 of the semiconductor structure 28. The lower surface 24 of the substrate is directly connected with the upper surface 27 of the semiconductor structure 28 by a fusion bonding process or a laser welding process. The fusion bonding process is performed at temperatures up to a melting point of the material of the substrate and/or up to a melting point of the material of the semiconductor structure 28. During this process, the connecting layer 14 is generated as a fusion bonding layer comprising melted and solidified materials of the lower surface 24 of the substrate 1 and/or melted and solidified material(s) of the upper surface 27 of the semiconductor structure 28.

Depending on the used embodiment there may be a further layer on the surface 27 of semiconductor structure 28 of the wafer 15 that is for example made of sapphire. In this embodiment, the connecting layer 14 is arranged between the converter 5 and the further layer. The substrate 1 of the converter 5 is for example made of sapphire or glass.

The connecting layer 14 may have a thickness smaller than 10 μm, preferably smaller than 5 μm, for example, 1 μm. The connecting layer 14 is made of a material that is transparent for the light that is emitted by the pn interface 29 of the semiconductor structure 28.

FIG. 3 shows a schematic view of a part of the wafer 15 that is connected via the connecting layer 14 to the converter 5 according to FIG. 2. The connecting layer 14 and the converter 5 may have the same area as the wafer 15. The arrangement of the wafer 15 with the semiconductor structure 28 and the converter 5 that is fixed by the connecting layer 14 can be divided to form individual light emitting units 19. Separation lines 43, 44 along the surface of wafer 15 are depicted schematically as dashed lines. The dicing of the light emitting units 19 can be accomplished by sawing, scratching and breaking or laser cutting.

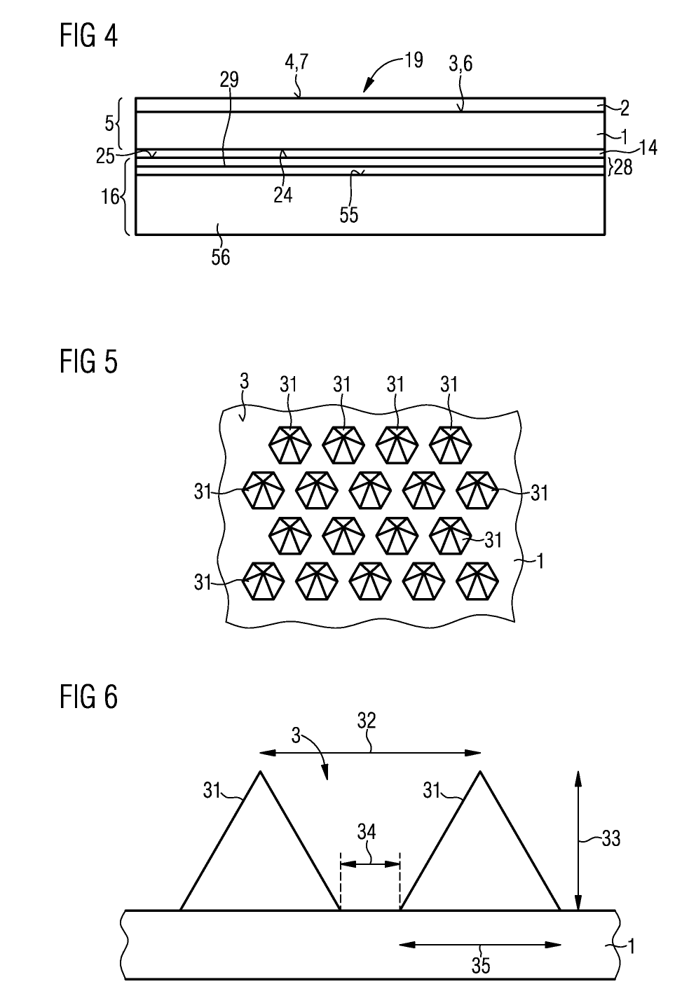

FIG. 4 shows a schematic cross sectional view of a light emitting unit 19. The light emitting unit 19 may be separated from the wafer 15 with the converter 5 as shown in the FIG. 3. However, the light emitting unit 19 may also be fabricated in different ways. The light emitting unit 19 comprises a light emitting semiconductor chip 16 with a wavelength converter 5. The converter 5 may have the same structure as explained with respect to FIGS. 1 to 3. The semiconductor chip 16 comprises a further substrate 56 with the semiconductor structure 28. A lower surface 24 of the substrate 1 of the converter 5 is fixed to a connecting layer 14. The connecting layer 14 is arranged on a light emitting surface 25 of the semiconductor chip 16. The light emitting surface 25 is an upper surface of the light emitting semiconductor chip 16. In the shown embodiment, the light emitting surface 25 is the upper surface 27 of the semiconductor structure 28. However, depending on the used embodiment, also a further layer may be arranged on the upper surface 27 of the semiconductor structure forming the light emitting surface 25. The connecting layer 14 fixes the converter 5 to the light emitting surface 25 of the semiconductor chip 16. The connecting layer 14 may have the same area as the light emitting surface 25 of the semiconductor chip 16. The connecting layer 14 may have a thickness smaller than 10 μm, preferably smaller than 5 μm.

Depending on the used embodiment, also a single light emitting semiconductor chip 16 with a light emitting semiconductor structure 28 with an active region, e.g. a pn interface 29, can be connected to a converter 5 by a connecting layer 14 as explained referring to FIG. 2 for a wafer 15.

FIG. 5 shows a schematic top view of a first surface 3 of a substrate 1 that is embodied as a sapphire substrate with the hexagonal patterns of projection 31 as discussed above.

FIG. 6 shows a partial cross section of the first surface 3 of the substrate 1 of FIG. 5 in an enlarged view. The projections 31 are arranged with a pitch 32 of about 3.5 μm or smaller between two projections 31. The projections 31 may have a height 33 from a plane surface to a tip of the projection of about 0.6 μm up to 2.0 μm, preferably between 1.2 μm and 1.6 μm. The projections 31 may have a distance 34 of about 0.5 to 1 μm between two projections 31 at the surface level. Furthermore, the projections may have a width 35 at the surface level between 1.3 μm and 2.8 μm.

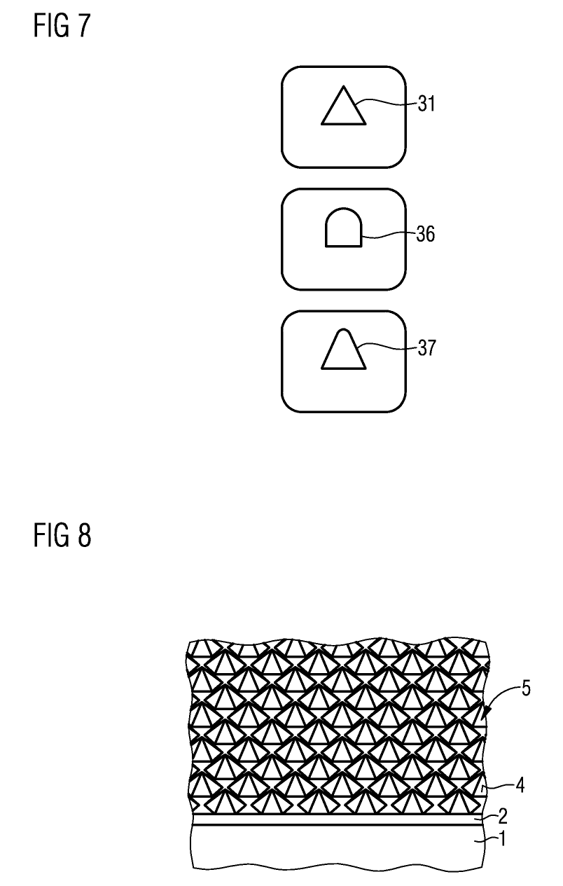

FIG. 7 shows different shapes of projections. The projection 31 has a cone shape. A second projection 36 has a dome shape and a third projection 37 has a pyramid shape with a rounded tip and for example with a square base. Depending on the used embodiment, the projections of the first surface 3 and/or of the second surface 4 of the conversion layer 2 may comprise one of these types of projections. Depending on the used material for the substrate 1 the projections of the first and second surfaces 3, 4 may have different or similar shapes.

FIG. 8 shows the substrate 1 of FIG. 5 after the deposition of a conversion layer 2. The second surface 4 of the conversion layer 2 has an identical or at least a similar structure as the first surface of the substrate 1. After the deposition, an annealing of the deposited conversion layer 2 can be performed at a temperature of about 1600° C. in an atmosphere of 3 to 6% hydrogen gas combined with nitrogen and/or argon gas.

The roughness of the first surface 3 determines the roughness of the second surface 4 of the conversion layer 2. It is much easier to process the first surface of the substrate than to process the second surface of the very thin conversion layer. The thin conversion layer 2 provides a high thermal dissipation due to a larger contact surface area between the conversion layer and the substrate 1. There is no need to use bonding material to fix the conversion layer 2 to the substrate 1. So, there is no diffusion of bonding material into the conversion layer that may cause a degradation in light quality. Furthermore, there is no need to engineer the second surface of the conversion layer after the deposition of the conversion layer on the first surface of the substrate 1.

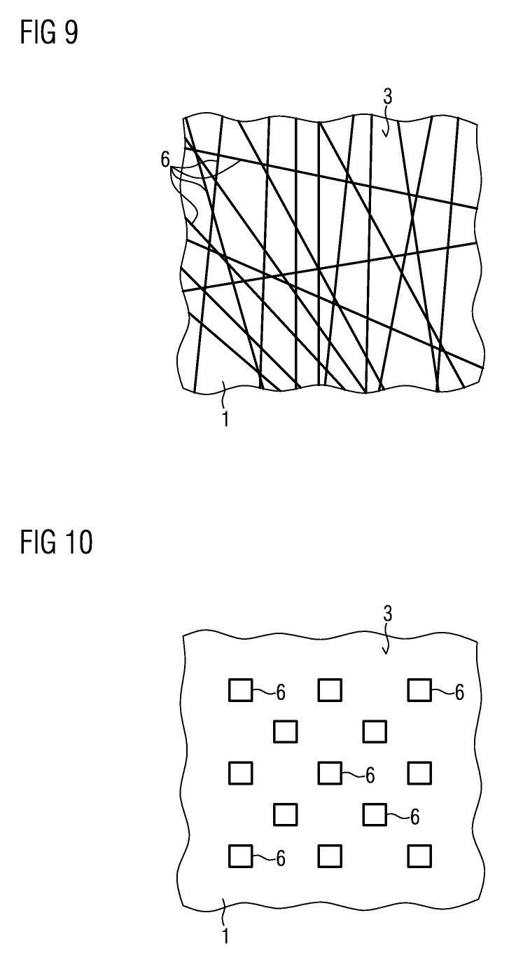

FIG. 9 is a schematic top view of a substrate 1 with a structured first surface 3 that is generated by a mechanical polishing process. The first surface 3 comprises first recesses 6 that are embodied as scratches and/or as recesses with different shapes and/or with a random distribution. After the deposition of the conversion layer 2 on the first surface 3, the second surface 4 of the conversion layer 2 has the same or similar structure as the first surface 3. This means that the second surface 4 comprises second recesses that are embodied as scratches and/or as recesses with different shapes and/or with a random distribution.

FIG. 10 shows a further embodiment of a structured first surface of a substrate 1 that comprises first recesses 6 with a regular pattern and with a similar or identical shape of each first recess 6. After the deposition of the conversion layer 2 on the first surface 3, the second surface 4 of the conversion layer 2 has the same or similar structure as the first surface 3. This means that the second surface 4 also comprises a regular pattern of second recesses with a similar or identical shape of each second recess.

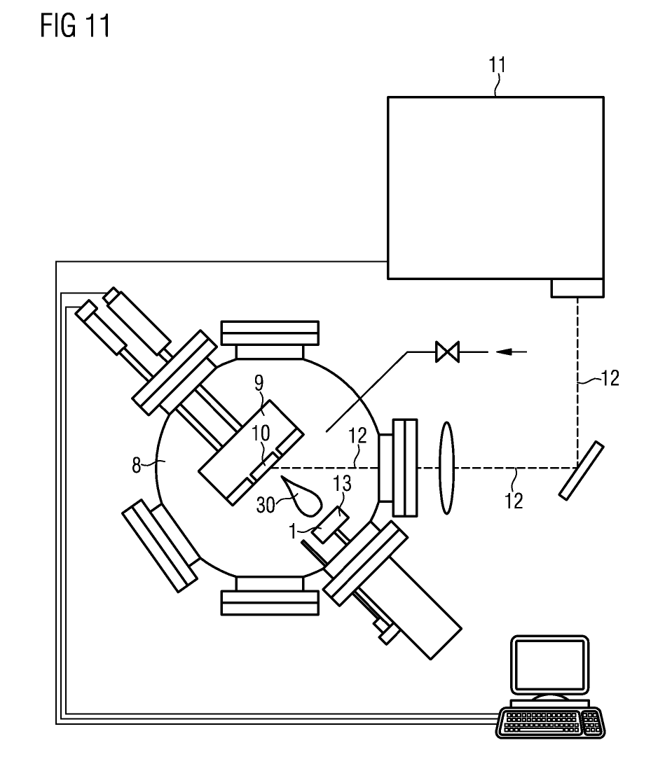

FIG. 11 shows a schematic view of an apparatus for a pulsed laser vapour deposition process. For a pulsed laser deposition process, the substrate may be heated to a temperature of about 700° C. in a vacuum chamber 8 with a pressure of about 3 m torr oxygen partial pressure. Then by using the pulsed laser deposition technique the luminescent material for example YAG: Ce material is deposited on the first surface 3 of a substrate 1. A vacuum chamber 8 with a holder 9 for a target 10 is arranged. The target 10 is made of luminescent materials, especially of crystalline luminescent materials. A pulsed laser beam 12 is generated for example by a KrF gas laser 11. The laser beam 12 is guided to the target 10. The laser beam 12 solves material 30 out of the target 10. The free material 30 is deposited on the substrate 1 which is fixed to a substrate holder 13.

The pulsed laser deposition technique is a physical vapor deposition process. High laser energy density is used to vaporize or to ablate material 30 from the target 10 and to create a plasma plume of material 30. The plasma plume consists of atomic, diatomic species of material 30 of the luminescent material of the target 10. The selected target material has an impact on properties of the deposited layer as for example particulate density, epitaxy, face formation, deposition rate, and material stoichiometry. The pulsed laser deposition process can be used for any kind of complex materials such as luminescent materials. Furthermore, a wide range of pressure, a wide range of materials can be used. Furthermore, the pulsed laser deposition technique allows depositing thin conversion layers 2 on a first surface 3 of a substrate 1 with first recesses 6 implies there could be a lattice mismatch of less than 20% between the substrate and the thin film conversion layer. The laser vapor deposition method allows forming a conversion layer with a monocrystalline, a nearly monocrystalline or a poly-crystalline or an amorphous structure with a small thickness. A thin conversion layer deposited via laser vapour deposition method on the substrate with a structured first surface makes a micrometer-sized converter possible. The laser vapour deposition method preserves the structured first surface pattern in the second surface of the conversion layer. The structured second surface enhances the converted light scattering and thus increases the luminous flux of the converter.

For example, the target 10 may be arranged at a distance of about 7 cm with respect to the substrate 1. Furthermore, the target is rotated relatively to the substrate with an angular speed of about 80 to 100 degrees per second. A typical deposition rate of YAG:Ce about 1 μm per hour was attained. After the deposition of the conversion layer, the substrate 1 may be annealed at a temperature between 1400° C. and 1800° C., preferably at a temperature between 1500° C. and 1700° C.

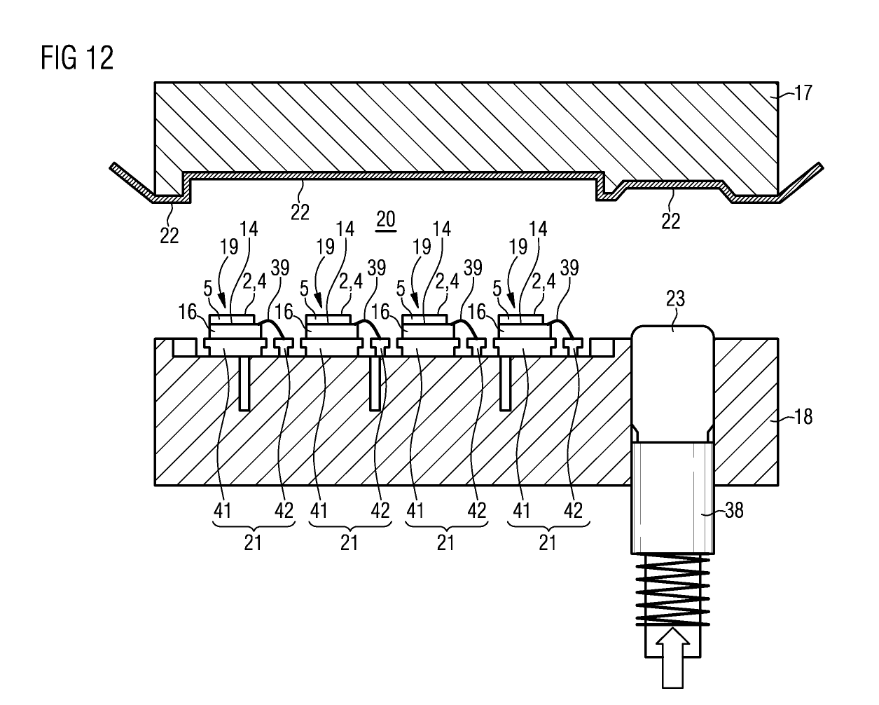

FIG. 12 shows a schematic cross sectional view of a molding apparatus with the first and the second molding tools 17, 18, wherein light emitting units 19 are arranged in a molding chamber 20 between the first and the second molding tools 17,18. Each light emitting unit 19 comprises a light emitting semiconductor chip 16, a connecting layer 14 and a converter 5. The converter 5 comprises an upper side conversion layer 2 with the structured second surface 4. The light emitting semiconductor chip 16 is arranged on a first lead frame 41. A first electrical contact of the semiconductor chip 16 is connected by a bond wire 39 with a second lead frame 42. The first and the second lead frames 41, 42 may be made of copper. Furthermore, the lead frames 41, 42 may be covered with a coating layer or plating layer that is made of NiPdAu or NiAg. The second electrical contact of the semiconductor chip 16 is arranged on a lower surface of the semiconductor chip 16 and is in contact with an upper face of the first lead frame 41. The first and the second lead frames 41,42 are arranged on the second molding tool 18. The first lead frame 41 constitutes a carrier for the light emitting semiconductor chip 16. Depending on the used embodiment, the lead frames 41, 42 of the light emitting units 19 may be connected to a lead frame plate. Depending on the used embodiment, also separated lead frames 41,42 can be arranged in the chamber 20.

A lower side of the first tool 17 is dedicated to an upper side of the second tool 18 on which the lead frames 41,42 with the semiconductor chips 16 are arranged. At the lower side of the first tool 17 a film 22 is arranged.

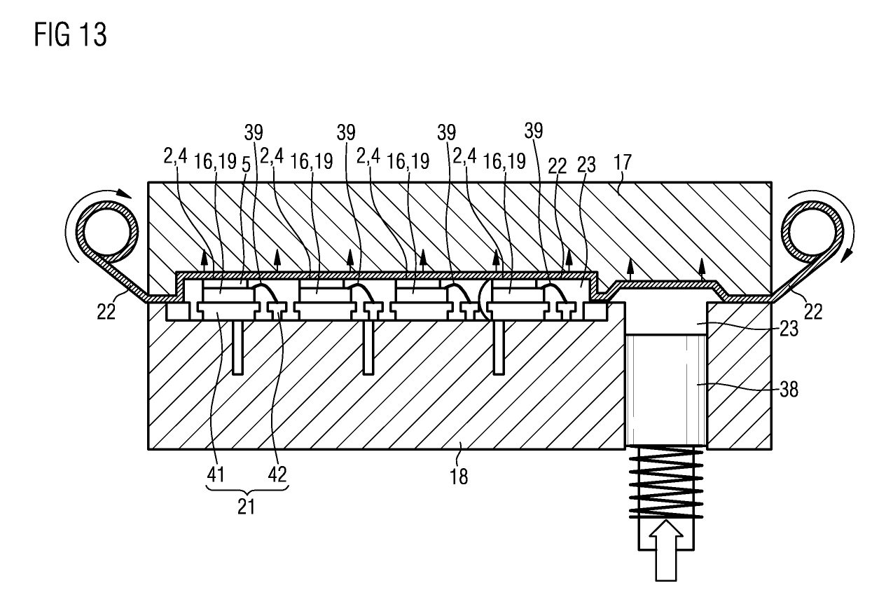

FIG. 13 shows the molding tools 17, 18 in a closed position, whereby the film 22 covers the second surfaces 4 of the conversion layers 2 of the converters 5 of the light emitting units 19. Since the film 22 is made of a flexible material, the structured second surface 4 can be safely sealed against molding material 23 that is pushed into the chamber 20 by a piston 38. The film-assisted molding technique can especially be used for the proposed light emitting unit 19 with a conversion layer 2 with a structured second surface 4 to embed the light emitting unit 19 in a housing made of molding material 23. The molding material can, for example, be made of plastic, silicone or epoxy material.

After the molding process, the two molding tools 17,18 are separated as shown in FIG. 12 and the light emitting units 19 that are embedded in a housing plate made of molding material 23 can be taken out of the chamber 20. Then the housing plate is separated as single light emitting units 19 that are embedded in a housing made of molding material 23.

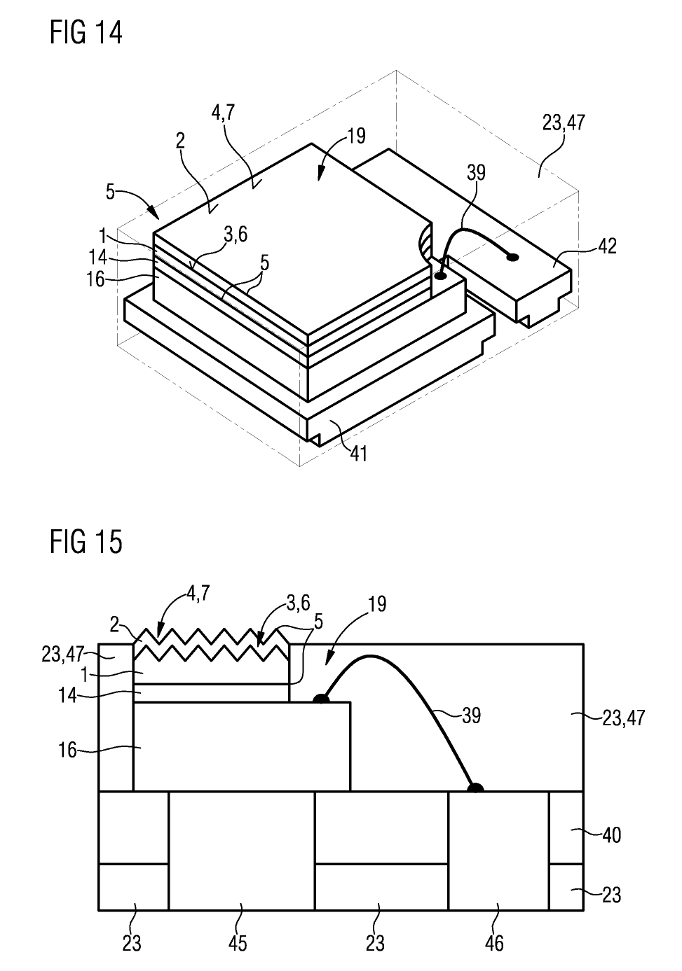

FIG. 14 shows a perspective view of a single light emitting unit 19 that is embedded in a housing 47 that is made of molding material 23. The housing 47 is depicted as transparent here, whereas opaque or white appearance may be selected. Two lead frames 41,42 are embedded in the housing 47. A first electrical contact of the semiconductor chip 16 is connected by a bond wire 39 with the second lead frame 42. The second electrical contact of the semiconductor chip 16 is arranged on a lower surface of the semiconductor chip 16 and is in contact with an upper face of the first lead frame 41. The conversion layer 2 is not covered by the housing 47 nor the molding material 23. The light emitting unit 19 comprises a semiconductor chip 16 with a converter 5. The converter 5 has a substrate 1 with a first surface 3 with recesses 6. On the first surface 3 of the substrate 1 the conversion layer 2 is arranged. The conversion layer 2 has at an upper side the second surface 4 with second recesses 7. The light emitting unit 19 may be embodied and produced as discussed in the above examples. The embedding in the housing may be performed by a film assisted molding process as explained with respect to the FIGS. 12 and 13.

FIG. 15 shows a schematic cross sectional view of a further embodiment of a light emitting unit 19 with a light emitting semiconductor chip 16, with a connecting layer 14, a converter 5 with a substrate 1 and a conversion layer 2. The substrate 1 has at an upper side a first surface 3 with recesses 6. On the first surface 3 of the substrate 1 the conversion layer 2 is arranged. The conversion layer 2 has at an upper side the second surface 4 with second recesses 7. The light emitting unit 19 may be embodied and produced as discussed in the above examples. The light emitting semiconductor chip 16 is arranged on a printed circuit board 40 as a carrier. The printed circuit board 40 has two via connections 45, 46 that are arranged in a core material. The core material may for example be FR-4. A first electrical contact of the semiconductor chip 16 is connected by a bond wire 39 with the second via connection 46. The second electrical contact of the semiconductor chip 16 is arranged on a lower surface of the semiconductor chip 16 and is in contact with an upper face of the first via connection 45. The light emitting unit 19 is embedded in a housing 47 made of molding material 23. The embedding may be performed by a film assisted molding process as explained with respect to FIGS. 12 and 13. The conversion layer 2 is not covered by the molding material 23 of the housing 47.

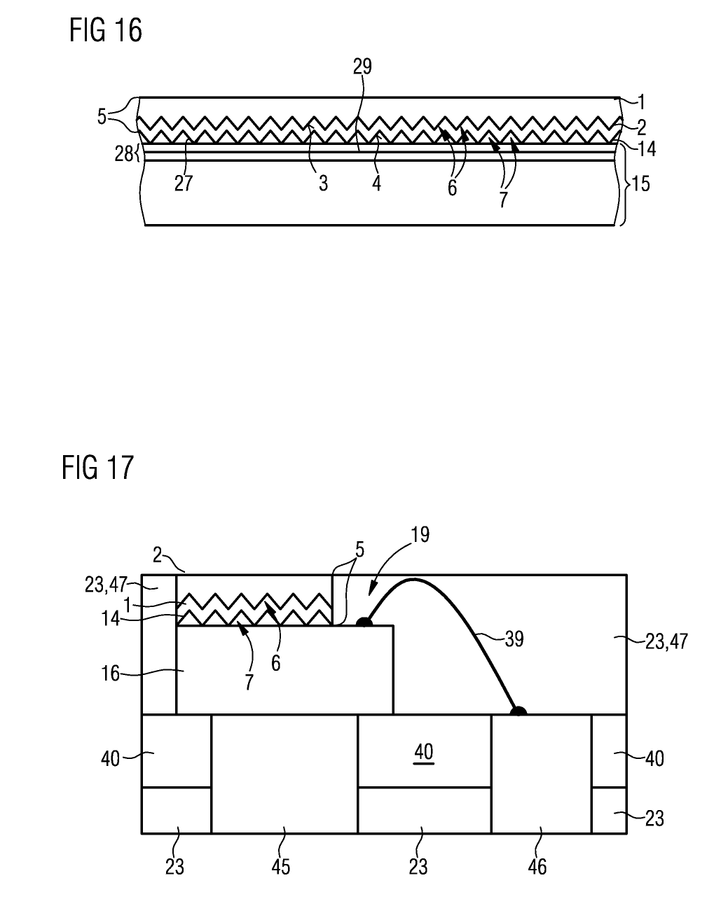

FIG. 16 shows a further embodiment that is similar to the embodiment of FIG. 2, wherein in this embodiment the converter 5 is rotated 180°. The second surface 4 with the second recesses 7 of the conversion layer 2 is directed to the upper surface 27 of the wafer 15 and the second surface 4 with the second recesses 7 is fixed by a connecting layer 14 to the upper surface 27 of the wafer 15. The converter 5 has a substrate 1 with a first surface 3 with recesses 6. On the substrate 1 the conversion layer 2 is arranged. The conversion layer 2 has at a lower side the second surface 4 with second recesses 7.

The wafer 15 may have the same structure and features as discussed with respect to the embodiment of FIG. 2. The wafer 15

Comprises at the upper surface 27 a semiconductor structure 28 with several semiconducting layers with an active region, e.g., a pn interface 29, that is embodied to generate light. The semiconductor structure 28 is, for example, made of epitaxial layers of semiconductor materials combining group III elements with group V elements, for example, boron, aluminum, gallium, indium with nitrogen, phosphorus, arsenic, antimony, bismuth. The range of possible formulae is quite broad because these elements can form binary (two elements, e.g. gallium(III) arsenide (GaAs)), ternary (three elements, e.g. indium gallium arsenide (InGaAs)) and quaternary (four elements, e.g., aluminum gallium indium phosphide (AlInGaP)) alloys.

The connecting layer 14 is arranged on the upper surface 27 of the wafer 15. The connecting layer 14 may be embodied as a foil which means a sheet layer. The connecting layer 14 may have the same area as the wafer 15. The connecting layer 14 may have a thickness smaller than 10 μm, preferably smaller than 5 μm, for example, 1 μm. However, the connecting layer 14 may also have a larger thickness.

The connecting layer 14 may, for example, comprise silicone or may be embodied as a silicone layer. The connecting layer 14 may comprise a silicone matrix material based on methyl or phenyl. Furthermore, the connecting layer 14 with silicone may comprise filler for example spacer particles made of TiO₂ or SiOₓ. The connecting layer 14 may have a thickness smaller than 10 μm, preferably smaller than 5 μm. The connecting layer 14 is made of a material that is transparent for at least 50% of the light that is emitted by the light emitting semiconductor structure 28.

The connecting layer 14 may, for example, be embodied as a silicone layer. The connecting layer 14 may comprise a silicone matrix based on methyl or phenyl. Furthermore, the connecting layer may comprise filler material for example spacer and/or TiO₂ and/or SiOₓ.

The connecting layer with silicone is an adhesive layer. The converter 5 may be fixed to the wafer 15 by a lamination process that generates an adhesive connection between the substrate and the connecting layer and between the connecting layer and the wafer 15. The lamination process can be performed at room temperature or at higher temperatures above 100° C.

In a further embodiment, the connecting layer comprises inorganic material for example glass or may be made of glass. In this embodiment, the connecting layer is arranged between the second recesses 7 of the conversion layer 2 of the converter 5 and the upper surface 27 of the wafer 15. Then the converter 5 is fixed to the wafer 15 by an inorganic fusing process, for example by a glass fusing process that generates inorganic fusion bonding connections between the conversion layer 2 and the connecting layer 14 and between the connecting layer 14 and the wafer 15. The inorganic fusing process, especially the glass fusing process is performed at temperatures up to a melting point of the glass. In a further embodiment, the connecting layer comprises or is made of silicon dioxide.

In a further embodiment, the connecting layer 14 is generated by a fusing process without providing a separate connecting layer material. The converter 5 is put with the rough surface 7 of the conversion layer 2 on the upper surface 27 of the wafer 15 which means on the upper surface of the semiconductor structure 28 of the wafer 15. The rough surface 7 of the conversion layer 2 is directly connected with the upper surface 27 of the wafer 15 by a fusion bonding process. The fusion bonding process is performed at temperatures upto a melting point of the material of the substrate and/or up to a melting point of the material of the light emitting surface of the semiconductor chip.

During this process, the connecting layer 14 is generated as a fusion bonding layer comprising melted and solidified materials of the rough surface 7 of the conversion layer 2 and/or melted and solidified material(s) of the upper surface 27 of the wafer 15. The upper surface 27 of the wafer 15 is for example made of semiconductor material. Depending on the used embodiment there may be a further layer on the semiconductor structure 28 of the wafer 15 that is for example made of sapphire. The substrate is, for example, made of sapphire or glass.

The connecting layer 14 may have a thickness smaller than 10 μm, preferably smaller than 5 μm, for example, 1 μm. The connecting layer 14 is made of a material that is transparent for the light that is emitted by the pn interface 29 of the semiconductor structure 28.

The converter 5 may have the same or similar technical features as the converter 5 of the embodiment of FIG. 2 that were explained with respect to the FIGS. 5 to 10. Furthermore the wafer with the converter can be separated into light emitting units. The converter 5 may be produced using a pulsed laser vapor deposition process as explained with regard to FIG. 11.

FIG. 17 shows a schematic cross sectional view of a further embodiment of light emitting unit 19 that is separated from a wafer 15 with a converter 5 as shown in FIG. 16. The light emitting semiconductor chip 16 is connected by the connecting layer 14 with the rough surface 7 of the conversion layer 2 of the converter 5. The light emitting semiconductor chip 16 is arranged on a printed circuit board 40 as a carrier. The printed circuit board 40 has two via connections 45, 46 that are arranged in a core material. The core material may for example be made of FR-4. A first electrical contact of the semiconductor chip 16 is connected by a bond wire 39 with the second via connection 46. The second electrical contact of the semiconductor chip 16 is arranged on a lower surface of the semiconductor chip 16 and is in contact with an upper face of the first via connection 45. The light emitting unit 19 is embedded in a housing 47 made of molding material 23. The embedding may be performed by a film assisted molding process as explained with respect to FIGS. 12 and 13. The upper side of the substrate 1 is not covered by the molding material 23 of the housing 47.

Depending on the used embodiments, instead of incorporating a printed circuit board as a carrier, the light emitting units 19 may comprise a ceramic substrate with via connections 45, 46.

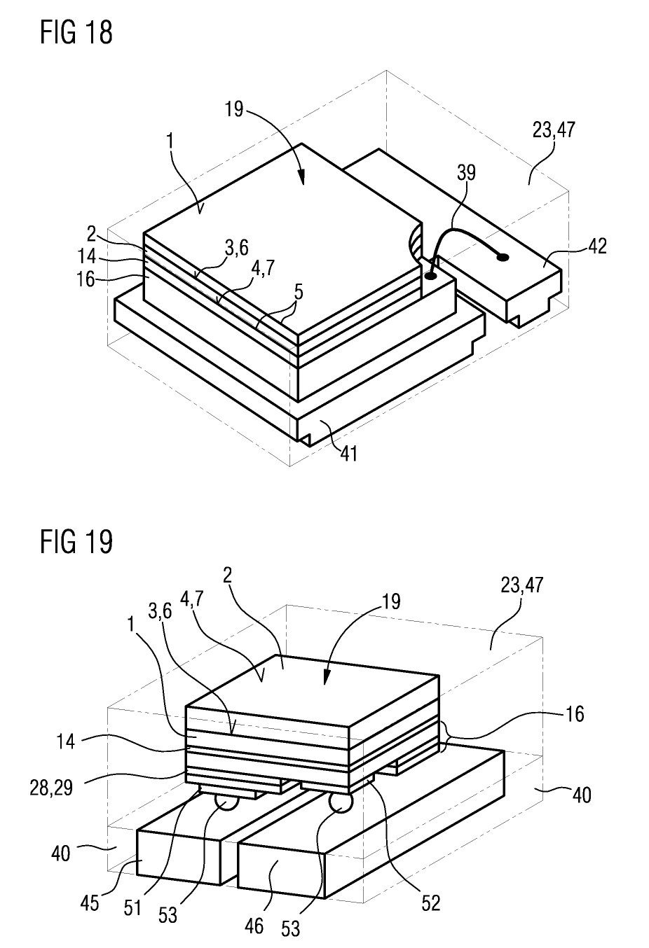

FIG. 18 shows a perspective view of a single light emitting unit 19 that is separated from the embodiment shown in FIG. 16. The light emitting unit 19 is embedded in a housing 47 that is made of molding material 23, wherein two lead frames 41 and 42 are embedded in the housing 47. Lower faces of the two lead frames 41,42 can be connected at a bottom face of the housing 47. The housing 47 is depicted as transparent here, whereas opaque or white appearance may be selected. The light emitting unit 19 may be embodied as discussed in the above examples. The embedding in the housing 47 may be performed by a film assisted molding process as explained with respect to the FIGS. 12 and 13. The upper side of the substrate 1 is not covered by the molding material 23 of the housing 47.

FIG. 19 shows a schematic cross sectional view of a further embodiment of a light emitting unit 19 that is mounted as a flip chip on a printed circuit board 40. The light emitting unit 19 is embodied as explained with respect to FIG. 14. The light emitting unit 19 has a light emitting semiconductor chip 16, a connecting layer 14, a converter 5 with a substrate 1 and a conversion layer 2. A lower side of the substrate 1 is connected by the connecting layer 14 with a upper side of the light emitting semiconductor chip 16 opposite to the semiconductor structure 28 with the pn interface 29. The substrate 1 comprises at an upper side the first surface 3 with the first recesses 6. On the first surface 3 with the first recesses 6 the first conversion layer 2 with an upper rough second surface 4 with second recesses 7 is arranged. The second surface 4 with the second recesses 7 are arranged opposite to the substrate 1. The first recesses 6 of the first surface 3 of the substrate 1 and the second recesses 7 of the second surface 4 of the conversion layer 2 are not depicted in detail. The connecting layer 14 connects a upper side of the semiconductor chip 16 with a bottom side of the substrate 1.

The light emitting semiconductor chip 16 and the converter 5 may have the same or similar features as discussed with regard to the FIGS. 1 to 10. However in contrast to the FIGS. 1 to 10, the converter 5 is arranged on the upper side of the light emitting semiconductor chip 16 opposite to the semiconductor structure 28.

The light emitting unit 19 with a flip chip mounted semiconductor chip 16 is mounted on the printed circuit board 40. On an upper side of the semiconductor chip 16 a first electrical contact 51 and a second electrical contact 52 are provided that are used for providing current to the light emitting unit 19. The first electrical contact is electrically connected with a p side of the pn interface 29. The second electrical contact is electrically connected with an n side of the pn interface 29.

The printed circuit board 40 has two via connections 45,46. The first electrical contact 51 of the semiconductor chip 16 is connected by a solder bump 53 with the upper face of the first via connection 45. The second electrical contact 52 of the semiconductor chip 16 is connected by a further solder bump 53 with the upper face of the second via connection 46. The light emitting unit 19 is embedded in a housing 47 made of molding material 23. The embedding may be performed by a film assisted molding process as explained with respect to FIGS. 12 and 13. The upper side of the conversion layer 2 is not covered by the molding material 23 of the housing 47.

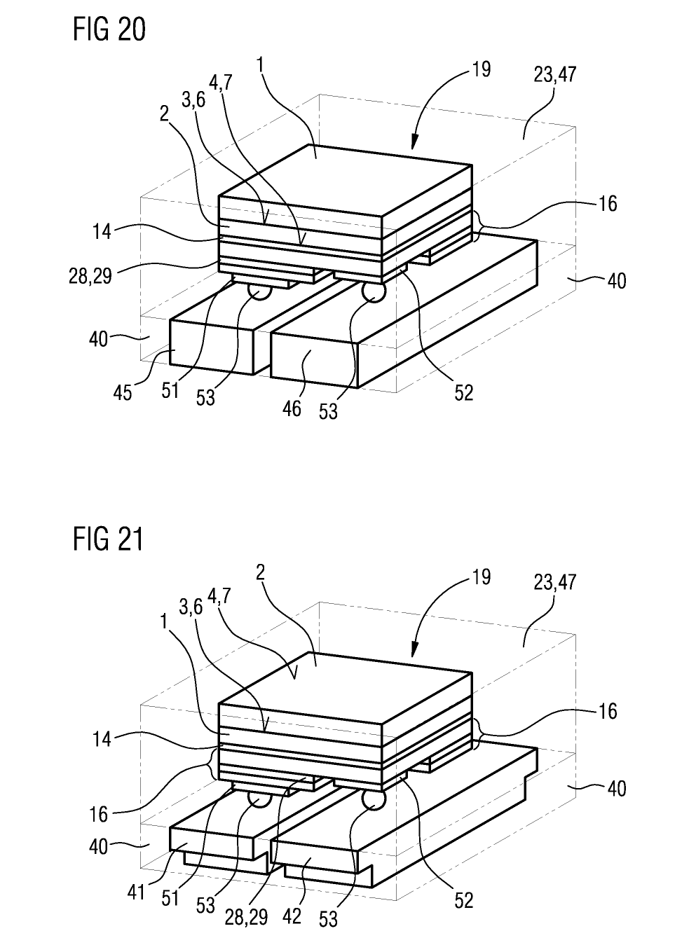

FIG. 20 shows a schematic cross sectional view of a further embodiment of a light emitting unit 19 with a flip chip mounted semiconductor chip 16 is mounted on the printed circuit board 40. The light emitting unit 19 comprises the light emitting semiconductor chip 16, a connecting layer 14 and a converter 5 with a substrate 1 and a conversion layer 2. In contrast to the embodiment of FIG. 19 the converter 5 is flipped 180°, wherein the second surface 4 of the conversion layer 2 with the second recesses 7 is connected by the connecting layer 14 with the upper face of the light emitting semiconductor chip 16. The conversion layer 2 is connected with a lower side of the substrate 1. The substrate 1 comprises at the lower side the first surface 3 with the first recesses 6.

Furthermore, the substrate 1 may have at an upper side a rough surface that is opposite to the conversion layer 2. In this embodiment, the substrate 1 may have at the first surface 3 recesses 6 or not. The first recesses 6 and the second recesses 7 are not depicted in detail. The substrate 1 and the conversion layer 2 may have the same or similar features as discussed with regard to the FIGS. 1 to 10 and 16. The upper side of the substrate 1 is not covered by the molding material 23 of the housing 47.

FIG. 21 shows a perspective view of a further embodiment of a light emitting unit 19 that is embodied as explained with respect to FIG. 19. The light emitting unit 19 is however not arranged on a printed circuit board but on lead frames 41, 42. The light emitting unit 19 is embedded in a housing 47 that is made of molding material 23, wherein the two lead frames 41,42 are embedded in the housing 47. Lower faces of the two lead frames can be connected from a bottom face of the housing 47. The housing 47 is depicted as transparent here, whereas opaque or white appearance may be selected. The light emitting unit 19 may be embodied as discussed in the above examples. The embedding in the housing 47 may be performed by a film assisted molding process as explained with respect to the FIGS. 12 and 13. The upper side of the conversion layer 2 is not covered by the molding material 23 of the housing 47.

The light emitting unit 19 with a flip chip mounted semiconductor chip 16 is mounted on the lead frames 41 and 42. On an upper side of the semiconductor chip 16 a first electrical contact 51 and a second electrical contact 52 are provided that are used for providing current to the light emitting unit 19. The first electrical contact is electrically connected with a p side of the pn interface 29. The second electrical contact is electrically connected with an n side of the pn interface 29. The first electrical contact 51 of the semiconductor chip 16 is connected by a solder bump 53 with the upper face of the first lead frame 41. The second electrical contact 52 of the semiconductor chip 16 is connected by a further solder bump 53 with the upper face of the second lead frame 42.

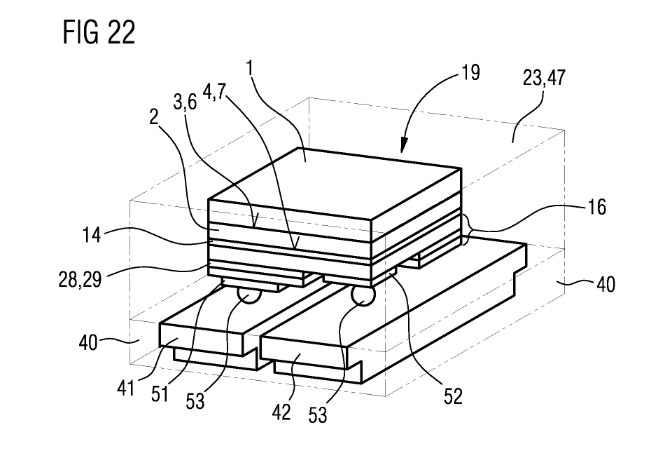

FIG. 22 shows a perspective view of a further embodiment of a single light emitting unit 19 that is embodied as explained with regard to FIG. 20. The light emitting unit 19 is however not arranged on a printed circuit board but on lead frames 41, 42. The light emitting unit 19 is embedded in a housing 47 that is made of molding material 23, wherein the two lead frames 41, 42 are embedded in the housing 47. Lower faces of the two lead frames 41, 42 can be connected from a bottom face of the housing 47. The housing 47 is depicted as transparent here, whereas opaque or white appearance may be selected. The light emitting unit 19 may be embodied as discussed in the above examples. The embedding in the housing 47 may be performed by a film assisted molding process as explained with respect to the FIGS. 12 and 13. The upper side of the substrate 1 is not covered by the molding material 23 of the housing 47.

A lower side of the conversion layer 2 with the second surface 4 and the second recesses 7 is connected by the connecting layer 14 with an upper side of the light emitting semiconductor chip 16 opposite to the semiconductor structure 28 with the pn interface 29. At an upper side of the conversion layer 2, the converter 5 comprises the substrate 1. The substrate 1 comprises in this embodiment at a lower side the first surface 3 with the first recesses 6. On the first recesses 6 the first conversion layer 2 with a lower rough surface with second recesses 7 is arranged. Furthermore, the substrate 1 may have at an upper side a rough surface that is opposite to the conversion layer 2. In this embodiment, the substrate 1 may have at the first surface 3 recesses 6 or not.

The light emitting unit 19 contains as a flip chip, wherein at a lower side of the semiconductor chip 16 a first electrical contact and a second electrical contact are provided that are used for feeding current to the light emitting unit 19. The first electrical contact is electrically connected with a p side of the pn interface 29. The second electrical contact is electrically connected with an n side of the pn interface 29. The first electrical contact of the light emitting semiconductor chip 16 is in contact with a first lead frame 41. The second electrical contact of the light emitting semiconductor chip 16 is in contact with a second lead frame 42.

The light emitting unit is embedded in a housing 47 that is made of molding material 23, wherein the two lead frames 41 and 42 are embedded in the housing 47. Lower faces of the two lead frames can be connected from a bottom face of the housing 47. The housing 47 is depicted as transparent here, whereas opaque or white appearance may be selected.

Further embodiments of the light emitting units 19 may be embodied with substrate-lean material(s) and omit the carrier. The light emitting units 19 comprise the light emitting semiconductor chip 16 according to any one of the above explained embodiments, wherein the light emitting semiconductor chip 16 is embedded in a housing 47 made of molding material. No lead frame or printed circuit board or ceramic substrate is part of the light emitting unit 19.

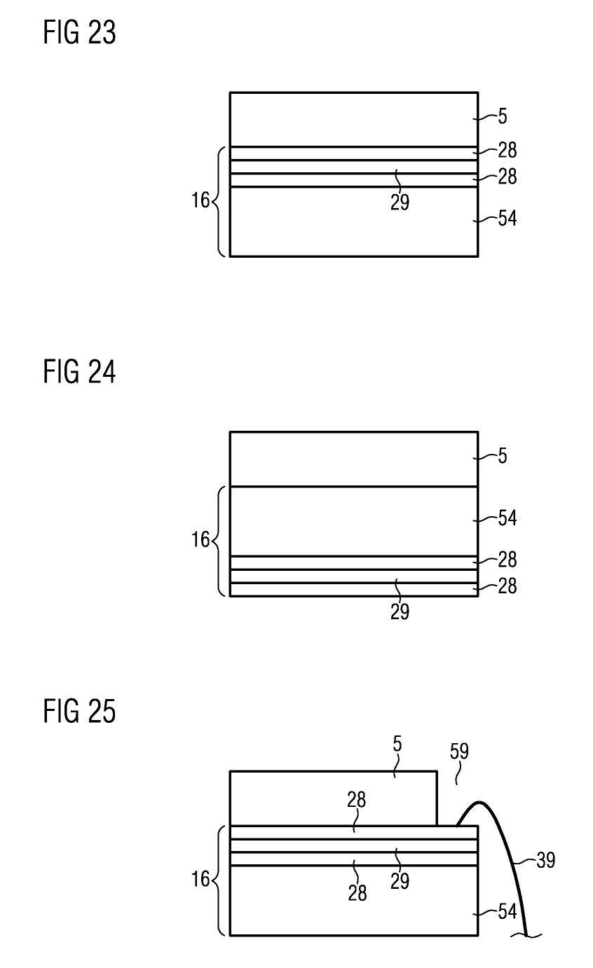

FIG. 23 depicts in a schematic view a further embodiment of a light emitting semiconductor chip 16 with a semiconductor structure 28 at an upper side. The semiconductor structure 28 comprises a pn interface 29 that is embodied to generate electromagnetic radiation especially visible radiation. On top of the semiconductor structure 28 may be made of epitaxial semiconductor layers. On top of the semiconductor structure 28 a converter 5 is arranged. The converter 5 may comprise a substrate and a conversion layer as explained above. Depending on the used embodiment, the substrate or the conversion layer is arranged on the upper side of the semiconductor structure 28. The semiconductor structure 28 may be arranged on top of a semiconductor chip substrate 54. The light emitting semiconductor chip 16 may be embodied as a flip chip top emitter.

FIG. 24 shows in a schematic view a further embodiment of a light emitting semiconductor chip 16 with a converter 5. In this embodiment, the semiconductor structure 28 with the pn interface 29 is arranged on a bottom of the chip substrate 54. On top of the chip substrate 54 a converter 5 is arranged. The converter 5 has a substrate and a conversion layer. The substrate comprises a first surface. The conversion layer is arranged on the first surface of the substrate. The conversion layer comprises opposite to the substrate a second surface. The first surface is not embodied as a plane surface but has a structured surface with first recesses. Therefore the first surface has a rough surface. The second surface of the conversion layer is not embodied as a plane surface but has a second surface with second recesses. The first and the second recesses are of similar and/or identical shape. The first and the second recesses have for example a similar shape if the shapes of the first and the second recesses differ less than 50% with respect to a height, a width, and/or an angular inclination of faces. Also, a pattern of the first recesses of the first surface is similar or identical to the pattern of the second recesses of the second surface. The meaning of recess covers any type of opening and any type of shape. Furthermore, the meaning of recess also covers an etched recess, especially an etched surface of a crystalline material. The converter 5 may comprise a substrate and a conversion layer as explained in the preceding FIGS. 1 to 22. Depending on the used embodiment, the substrate or the conversion layer of the converter 5 is arranged on top of the chip substrate 54. The light emitting semiconductor chip 16 may be embodied as one of the preceding described examples with respect to the FIGS. 1 to 22. In one embodiment, the light emitting semiconductor chip 16 is embodied as a flip chip volume emitter.

FIG. 25 depicts a third embodiment of a light emitting semiconductor chip 16 with a chip substrate 54, wherein on top of the chip substrate 54 the semiconductor structure 28 with the pn interface 29 is arranged. On top of the semiconductor structure 28 a converter 5 is arranged. The converter 5 comprises a substrate and a conversion layer. Depending on the used embodiment, the substrate or the conversion layer is arranged on the upper side of the semiconductor structure 28. Furthermore, a bond wire 39 is provided for electrically connecting one of the p layer or the n layer of the pn interface 29. The converter 5 has a recess 59 to provide space for guiding the bond wire 39 to an upper face of the semiconductor structure 28.

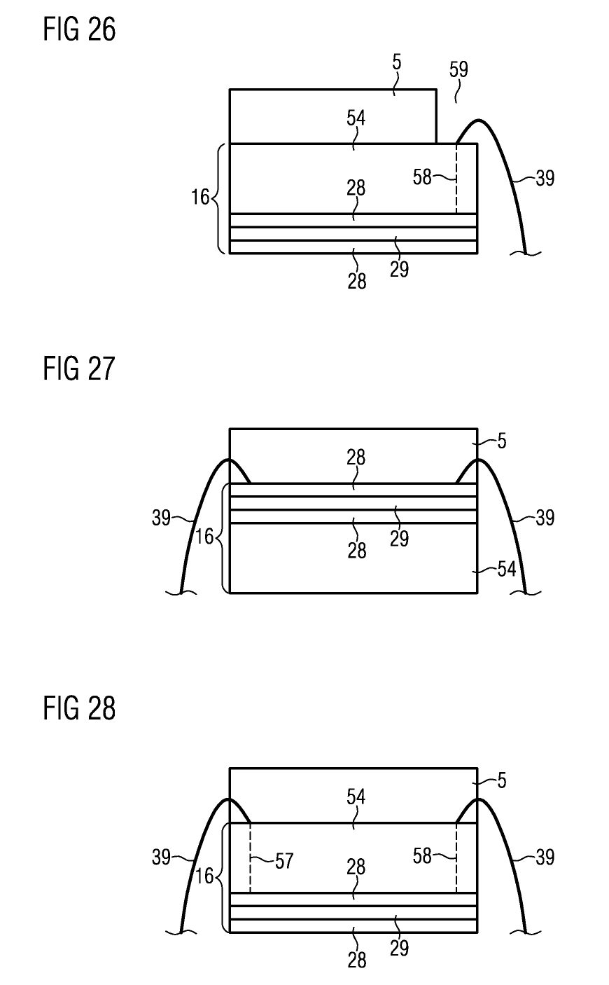

FIG. 26 shows in a schematic view a third embodiment of a light emitting semiconductor chip 16 with a chip substrate 54, wherein on bottom of the chip substrate 54 the semiconductor structure 28 with a pn interface is arranged. Furthermore, on top of the chip substrate 54 a converter 5 is arranged. The converter 5 comprises a substrate and a conversion layer. Depending on the used embodiment, the substrate or the conversion layer is arranged on top of the lighting emitting semiconductor chip 16. In this embodiment, the chip substrate 54 is embodied as a sapphire substrate. A bond wire 39 is provided for electrically connecting the p layer or the n layer of the pn interface 29. The converter 5 has a recess 59 to provide space for guiding the bond wire 39 to an upper face of the chip substrate 54. The bond wire 39 is connected with a via contact 58. The via contact 58 is guided through the chip substrate 54 to the p layer or the n layer of the pn interface 29.

FIG. 27 shows in a schematic view a third embodiment of a light emitting semiconductor chip 16 with a chip substrate 54, wherein on top of the chip substrate 54 the semiconductor structure 28 with a pn interface is arranged. Furthermore, on top of the semiconductor structure 28 a converter 5 is arranged. The converter 5 comprises a substrate and a conversion layer. Depending on the used embodiment, the substrate or the conversion layer is arranged on top of the semiconductor structure 28. In this embodiment, the chip substrate 54 is embodied as a sapphire substrate. Two bond wires 39 are provided electrically connecting the p layer and the n layer of the pn interface 29.

FIG. 28 shows a further embodiment of a light emitting semiconductor chip 16, wherein this embodiment the semiconductor structure 28 is arranged on the bottom of the chip substrate 54. On top of the chip substrate 54 the converter 5 is arranged. The converter 5 comprises a substrate and a conversion layer. Depending on the used embodiment, the substrate or the conversion layer is arranged on top of the chip substrate. The bond wires 39 are connected with via contacts 57, 58. The first via contact 57 is guided through the chip substrate 54 to the p layer of the pn interface 29. The second via contact 57 is guided through the chip substrate 54 to the n layer of the pn interface 29.

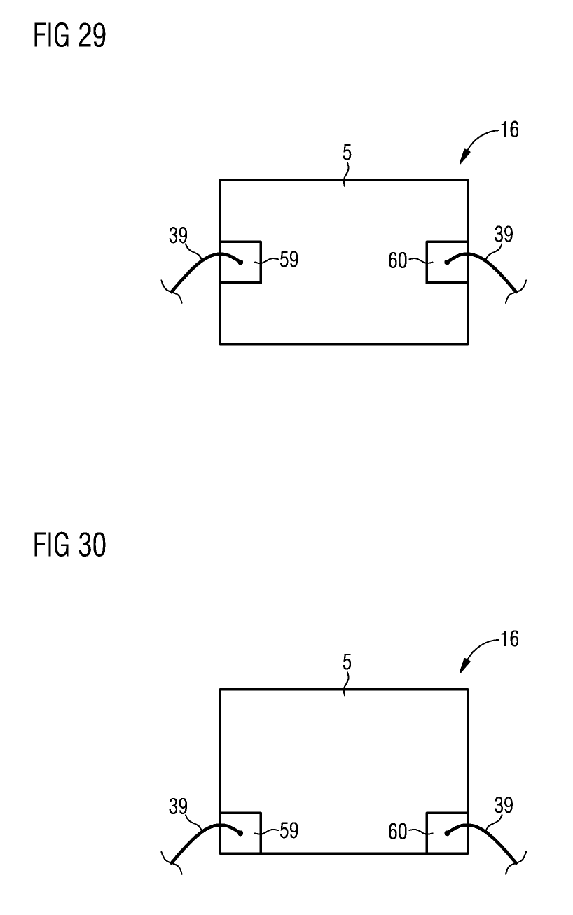

FIG. 29 shows a schematic view on a top of light emitting semiconductor chip 16 with a converter 5. The converter 5 has two recesses 59, 60 for providing space at an upper side of the semiconductor chip 16. The recesses 59, 60 are between corners of the converter 5. In this specific embodiment, the recesses 59, 60 are in a middle of a side length of the converter 5. The embodiments of FIG. 27 and FIG. 28 can have a converter 5 with recesses 59, 60.

FIG. 30 shows a schematic view on a top of light emitting semiconductor chip 16 with a converter 5. The converter 5 has two recesses 59, 60 for providing space at an upper side of the semiconductor chip 16. The recesses 59, 60 are arranged at corners of the converter 5. The embodiments of FIG. 27 and FIG. 28 can have a converter 5 with recesses 59, 60 at the corners of the converter 5.

The converter 5 in all the shown or discussed embodiments comprises a substrate and a conversion layer also the substrate and the conversion layer are not explicitly shown or explained.

Depending on the used embodiments, all the light emitting semiconductor chips 16 of the FIGS. 23 to 30 may comprise a mirror (e.g., a Bragg mirror) at the bottom of a light emitting semiconductor chip 16. The light emitting units 19 of the above described embodiments may comprise one of the light emitting semiconductor chips 16 as explained with reference to the FIGS. 23 to 30.

The above explained assembly concept is suitable for low, mid and high power light emitting modules for example in the fields of automotive, consumer and industry applications. The light emitting semiconductor chips 16 may be embodied as light emitting diodes or laser diodes.

The invention has been illustrated and described in detail with the aid of the preferred exemplary embodiments. Nevertheless, the invention is not restricted to the examples disclosed. Rather, other variants may be derived from here by a person skilled in the art without departing from the protective scope of the invention.

What is claimed is:

1. A light emitting unit comprising:
a light emitting semiconductor chip; and
a wavelength converter for the light of the semiconductor chip, wherein the wavelength converter comprises a substrate with a first surface that comprises a rough surface with recesses and a wavelength conversion layer arranged on the first surface of the substrate, the wavelength conversion layer having luminescent materials; and
a connecting layer arranged between the wavelength converter and a light emitting surface of the light emitting semiconductor chip.

2. The light emitting unit of claim 1, wherein the connecting layer is arranged between a second surface of the substrate of the wavelength converter and a light emitting surface of the light emitting semiconductor chip, the connecting layer fixing the substrate to the semiconductor chip.

3. The light emitting unit of claim 1, wherein the connecting layer is arranged between the wavelength conversion layer of the wavelength converter and a light emitting surface of the light emitting semiconductor chip, the connecting layer fixing the wavelength conversion layer to the semiconductor chip.

4. The light emitting unit of claim 1, wherein the connecting layer comprises silicone, and wherein the connecting layer provides an adhesive connection between the wavelength converter and the light emitting semiconductor chip.

5. The light emitting unit of claim 1, wherein the connecting layer comprises inorganic materials and wherein the wavelength converter and the semiconductor chip are connected by fusion bonding layer or laser welding layer as the connecting layer.

6. The light emitting unit of claim 1, wherein the connecting layer is embodied as a foil.

7. The light emitting unit of claim 1, wherein the connecting layer is a fusion bonding layer between the light emitting surface of the semiconductor chip and the wavelength converter.

8. The light emitting unit of claim 1, wherein the light emitting surface of the semiconductor chip comprises a semiconductor material or a substrate.

9. The light emitting unit of claim 1, wherein the connecting layer has a thickness smaller than 10 μm.

10. The light emitting unit of claim 1, wherein the wavelength conversion layer has a second surface that is opposite the substrate, and wherein the second surface has second recesses, the second recesses having similar and/or identical shapes as the recesses of the substrate of the wavelength converter.

11. The light emitting unit of claim 1, wherein the wavelength conversion layer comprises a monocrystalline or a polycrystalline or an amorphous layer of luminescent materials, and wherein the wavelength conversion layer has a thickness smaller than 100 μm.

12. The light emitting unit of claim 11, wherein the wavelength conversion layer has a thickness smaller than 20 μm.

13. A method for producing a light emitting unit, the method comprising:
providing a wavelength converter with a substrate and a wavelength conversion layer, wherein the substrate has a first rough surface with recesses;
arranging the wavelength conversion layer on the first rough surface of the substrate, wherein the wavelength conversion layer has luminescent materials;
providing a light emitting semiconductor structure with a light emitting surface; and
forming a connecting layer between the wavelength converter and the light emitting surface of the semiconductor structure, wherein the connecting layer fixes the wavelength converter to the light emitting semiconductor structure.

14. The method of claim 13, wherein the connecting layer is formed between a second surface of the substrate of the wavelength converter and a light emitting surface of the light emitting semiconductor structure or wherein the connecting layer is formed between the wavelength conversion layer of the wavelength converter and the light emitting surface of the light emitting semiconductor structure.

15. The method of claim 13, wherein the light emitting semiconductor structure is part of a wafer, and wherein, after the semiconductor structure is fixed to the wavelength converter by the connecting layer, the method further comprises separating the wafer with the connecting layer and the wavelength converter into single light emitting units.

16. The method of claim 13, further comprising performing a film assisted molding process so that the light emitting unit is embedded in a molding material, wherein a film protects an upper side of the light emitting unit during the molding process.

17. The method of claim 16, wherein the upper side of the light emitting unit is embodied as a second surface of the wavelength conversion layer, and wherein during the molding process the film protects the second surface of the wavelength conversion layer from molding material.

18. The method of claim 13, wherein the connecting layer comprises silicone and is arranged between the wavelength converter and the light emitting surface of the semiconductor structure, and wherein the wavelength converter is fixed to the light emitting semiconductor structure by a lamination process that generates an adhesive connection between the wavelength converter and the light emitting surface of the semiconductor structure by means of the connecting layer.

19. The method of claim 13, wherein the connecting layer comprises an inorganic material and is arranged between the wavelength converter and the light emitting surface of the semiconductor structure, wherein the wavelength converter is fixed to the light emitting semiconductor structure by a fusing process that generates a fusion bonding connection between the wavelength converter and the light emitting semiconductor structure by means of the connecting layer.

20. The method of claim 13, wherein the wavelength converter is put on the light emitting surface of the light emitting semiconductor structure, wherein the wavelength converter is connected with the light emitting surface of the light emitting semiconductor structure by a fusion bonding process or wherein the substrate is connected with the light emitting surface of the light emitting semiconductor structure by a fusion bonding process.
